(19) United States
(12) Patent Application Publication
(10) Pub. No.: US 2026/0181930 A1
(43) Pub. Date: Jun. 25, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Norio YASUHARA, Kanazawa Ishikawa (JP); Yoko IWAKAJI, Meguro Tokyo (JP); Daiki YOSHIKAWA, Nonoichi Ishikawa (JP); Kazutoshi NAKAMURA, Nonoichi Ishikawa (JP); Keiko KAWAMURA, Yokohama Kanagawa (JP)

(21) Appl. No.: 19/241,264

(22) Filed: Jun. 17, 2025

(30) Foreign Application Priority Data
Dec. 20, 2024 (JP) 2024-225678

(51) Int. Cl. H10D 12/00; H10D 62/10; H10D 64/27

(52) U.S. Cl. CPC H10D 12/481; H10D 62/103; H10D 62/126; H10D 64/311

(57) ABSTRACT

According to one embodiment, a semiconductor device includes a semiconductor member, a gate metal layer, a first gate electrode, and an emitter electrode. The gate metal layer includes a first portion and a second portion. The first gate electrode extends along a first direction, the first direction being from the first portion toward the second portion. The first gate electrode is connected to the gate metal layer in the first portion. The emitter electrode is provided on the semiconductor member. The emitter electrode includes a third portion and a fourth portion. The emitter electrode is electrically connected to the semiconductor member in the third portion and the fourth portion. The second portion is between the third portion and the fourth portion in the first direction.

### CROSS-REFERENCE TO RELATED APPLICATIONS

This application is based upon and claims the benefit of priority from Japanese Patent Application No. 2024-225678, filed on Dec. 20, 2024; the entire contents of which are incorporated herein by reference.

### FIELD

Embodiments described herein relate generally to a semiconductor device.

### BACKGROUND

It is desirable for semiconductor devices to prevent a decrease in RBSOA (reverse bias safe operating area).

### BRIEF DESCRIPTION OF THE DRAWINGS

FIG. 1 is a schematic plan view illustrating a semiconductor device according to an embodiment;

FIG. 2 is a schematic plan view illustrating the semiconductor device according to the embodiment;

FIG. 3 is a cross-sectional view taken along line A-A of FIG. 2;

FIG. 4 is a cross-sectional view taken along line B-B of FIG. 2;

FIG. 5 is a cross-sectional view taken along line C-C of FIG. 2;

FIG. 6 is an enlarged view of the periphery of a second portion;

FIG. 7 is a schematic plan view illustrating a semiconductor device according to a first modification of the embodiment;

FIG. 8 is a schematic plan view illustrating the semiconductor device according to the first modification of the embodiment;

FIG. 9 is a schematic plan view illustrating a semiconductor device according to a second modification of the embodiment; and

FIG. 10 is a cross-sectional view taken along line H-H of FIG. 9.

### DETAILED DESCRIPTION

### According to One Embodiment, a Semiconductor Device

includes a semiconductor member, a gate metal layer, a first gate electrode, and an emitter electrode. The gate metal layer includes a first portion and a second portion. The first gate electrode extends along a first direction, the first direction being from the first portion toward the second portion. The first gate electrode is connected to the gate metal layer in the first portion. The emitter electrode is provided on the semiconductor member. The emitter electrode includes a third portion and a fourth portion. The emitter electrode is electrically connected to the semiconductor member in the third portion and the fourth portion. The second portion is between the third portion and the fourth portion in the first direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

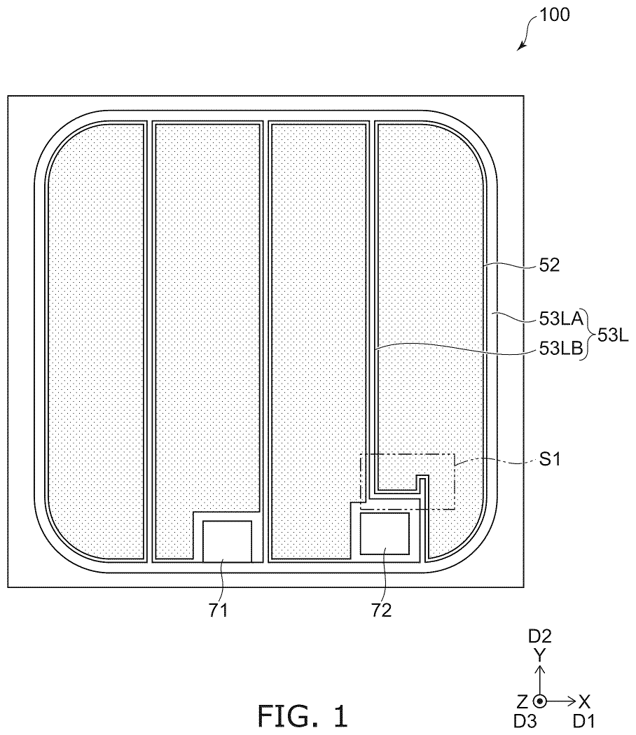

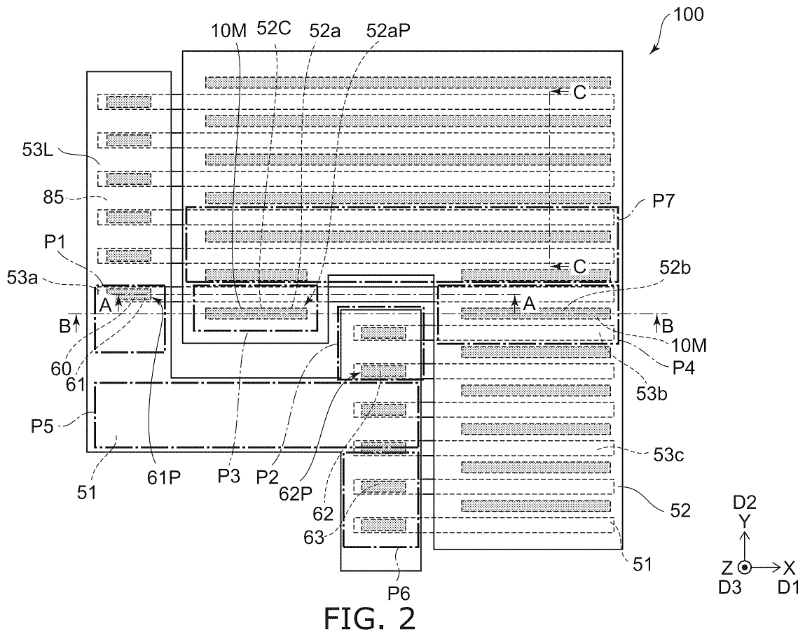

FIG. 1 and FIG. 2 are schematic plan views illustrating a semiconductor device according to an embodiment.

A semiconductor device 100 shown in FIG. 1 includes a semiconductor member 10M, a gate metal layer 53L including a first pad 71, a second pad 72, and an emitter electrode 52. The gate metal layer 53L includes a portion surrounding the emitter electrode 52 and a portion located between the emitter electrodes 52 in an X-Y plane. The first pad 71 is, for example, a gate pad.

A third direction D3 from a collector electrode 51 not shown in FIG. 1 to the emitter electrode 52 intersects with a first plane including a first direction D1 and a second direction D2. The semiconductor member 10M is between the collector electrode 51 and the emitter electrode 52.

The second pad 72 is electrically insulated from the gate metal layer 53L. The second pad 72 is, for example, a pad, such as a temperature sensing pad, a gate pad of a multi-gate, or a current sensing pad.

The emitter electrode 52 is provided apart from the gate metal layer 53L. The emitter electrode 52 is divided into a plurality of portions and provided. The gate metal layer 53L includes an outer periphery 53LA formed annularly to surround the plurality of emitter electrodes 52 in the X-Y plane. The gate metal layer 53L includes a wiring 53 LB connecting two sides of the outer periphery 53LA. As shown in FIG. 1, for example, the wiring 53 LB extends in a Y-direction and connects sides of the outer periphery 53LA extending in an X-direction. The wiring 53 LB connects opposing sides of the outer periphery 53LA.

The gate metal layer 53L including the wiring 53 LB is desirable to, when gate potential control of a gate electrode 53 (a first gate electrode 53a, a second gate electrode 53b, and a third gate electrode 53c) shown in FIG. 2 is performed, reduce a difference in timing of voltage application among the plurality of gate electrodes 53. Since not only the outer periphery 53LA but also the wiring 53 LB is connected to the gate electrode 53 and a voltage can be applied to the gate electrode 53, the distance between the gate electrode 53 and the gate metal layer 53L is reduced.

FIG. 2 shows a region S1 shown in FIG. 1.

As shown in FIG. 2, the semiconductor device 100 according to the embodiment includes the semiconductor member 10M (semiconductor substrate), the gate metal layer 53L, the first gate electrode 53a, and the emitter electrode 52.

A direction along the upper face of the semiconductor member 10M is defined as an X-axis direction. A direction along the upper face of the semiconductor member 10M and perpendicular to the X-axis direction is defined as a Y-axis direction. A direction perpendicular to the X-axis direction and the Y-axis direction is defined as a Z-axis direction. The X-axis direction is, for example, the first direction D1. The Y-axis direction is, for example, the second direction D2. The Z-axis direction is, for example, the third direction D3. The X-Y plane is, for example, the first plane.

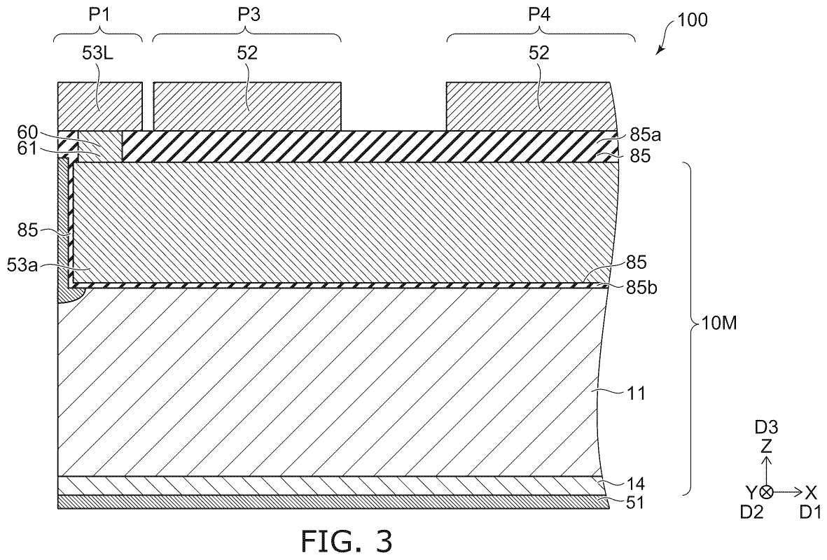

The gate metal layer 53L includes a first portion P1 and a second portion P2. Between the gate metal layer 53L and the semiconductor member 10M, an insulator 85 is provided, as will be described later with reference to FIG. 3. The insulator 85 includes an insulating layer 85a and a first insulating film 85b. The gate metal layer 53L is provided on the semiconductor member 10M with the insulating layer 85a interposed therebetween.

The first gate electrode 53a extends along the first direction D1, which is from the first portion P1 toward the second portion P2. The gate metal layer 53L is electrically connected to the first gate electrode 53a in the first portion P1. The first gate electrode 53a is, for example, the gate electrode 53 embedded in the semiconductor member 10M. The first gate electrode 53a faces the semiconductor member 10M with the first insulating film 85b interposed therebetween. For example, a transistor is formed in the semiconductor member 10M, and the conductivity of the transistor is controlled by applying a voltage to the first gate electrode 53a. The first gate electrode 53a is, for example, a trench gate electrode.

A plurality of gate electrodes 53 extend in the first direction D1.

The emitter electrode 52 is provided on the semiconductor member 10M. The emitter electrode 52 includes a third portion P3 and a fourth portion P4. The emitter electrode 52 is electrically connected to the semiconductor member 10M in the third portion P3 and the fourth portion P4. The second portion P2 is between the third portion P3 and the fourth portion P4 in the first direction D1.

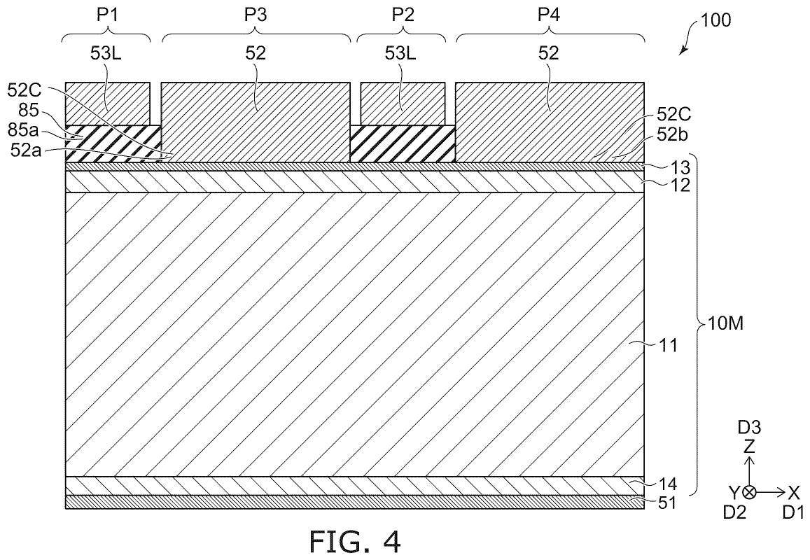

The semiconductor device 100 according to the embodiment includes the collector electrode 51 (see FIG. 3) and the insulator 85. The emitter electrode 52 includes an emitter contact 52C, which is in contact with the semiconductor member 10M, as will be described later with reference to FIG. 4. The emitter contact 52C includes a first emitter contact region 52a continuous with the third portion P3, and a second emitter contact region 52b continuous with the fourth portion P4.

The first insulating film 85b functions as a gate insulating film. The current flowing between the collector electrode 51 and the emitter electrode 52 can be controlled in accordance with the potential of the gate electrode 53. The semiconductor device 100 is, for example, an IGBT (Insulated Gate Bipolar Transistor).

At the time of conduction, carriers are accumulated in a region further outside the outermost first gate electrode 53a in the negative direction of the second direction D2. Considering a reference example in which the emitter electrode 52 does not include the third portion P3, a current crowding occurs on a contact of the active region at the time of turn-off and at the time of a load short-circuit, and destruction of the device due to the current crowding or latch-up may occur.

In the semiconductor device 100 according to the embodiment, the emitter contact 52C (first emitter contact region 52a) outside the active region allows the carriers to be discharged. This can prevent a decrease in RBSOA and SCSOA (short-circuit safe operating area).

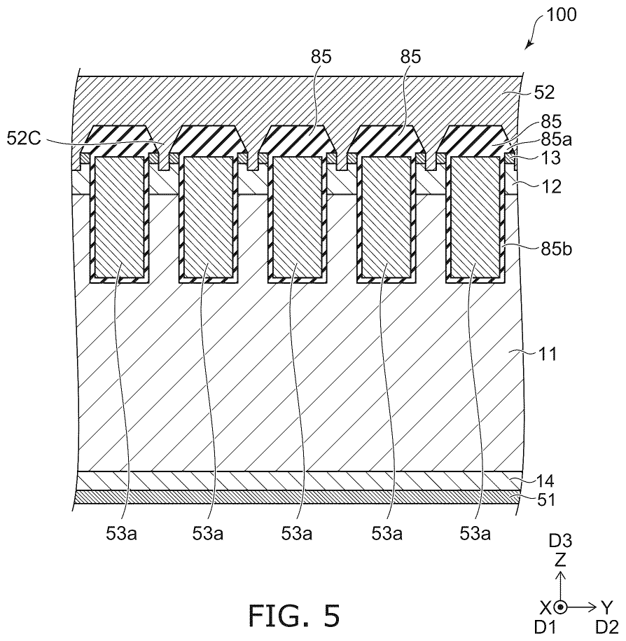

Note that the emitter contact 52C electrically connecting the emitter electrode 52 and the semiconductor member 10M does not necessarily extend into the semiconductor member 10M. However, it is desirable to make the emitter contact 52C extend into the semiconductor member 10M as shown later in FIG. 5 in order to increase the contact area between the emitter electrode 52 and the semiconductor member 10M.

As shown in FIG. 2, the length of the third portion P3 along the first direction D1 is longer than the length of the second portion P2 along the first direction D1. Further, the length of the third portion P3 along the first direction D1 is longer than the length of the first portion P1 along the first direction D1. As shown in FIG. 2, the length of the first gate electrode 53a in the first direction D1 in the third portion P3 is longer than the length of the first gate electrode 53a in the first direction D1 in the second portion P2.

FIG. 3 to FIG. 5 are cross-sectional views of the semiconductor device according to the embodiment.

FIG. 3 is a cross-sectional view taken along line A-A of FIG. 2.

FIG. 4 is a cross-sectional view taken along line B-B of FIG. 2.

FIG. 5 is a cross-sectional view taken along line C-C of FIG. 2.

A description will be given with reference to FIG. 3. FIG. 3 shows an example of a trench-gate-type semiconductor device. This does not prevent the embodiment from being applied to a planar-gate-type semiconductor device.

The insulating layer 85a is provided on the semiconductor member 10M, the first gate electrode 53a, and the first insulating film 85b. The insulating layer 85a is interposed between the first gate electrode 53a and the emitter electrode 52.

A connection member 60 (for example, a metal plug) electrically connects the first portion P1 and the first gate electrode 53a. The gate metal layer 53L and the first gate electrode 53a are electrically connected by the connection member 60.

In the example shown in FIG. 3, there is no electrical connection between the second portion P2 (not illustrated in FIG. 3) and the first gate electrode 53a. However, for example, in the same A-A cross section as in FIG. 3, a metal plug may be formed between the second portion P2 and the first gate electrode 53a if the second portion P2 reaches A-A line.

In the first insulating film 85b, an end in the first direction D1 may be covered with a semiconductor region having a conductivity type opposite to that of a first semiconductor region 11.

The gate metal layer 53L provided on the insulating layer 85a and the emitter electrode 52 are spaced apart from each other.

A description will be given with reference to FIG. 4.

As shown in FIG. 4, the emitter contact 52C is in contact with the semiconductor member 10M. At least a part of the emitter contact 52C extends along the first direction D1. The emitter contact 52C includes the first emitter contact region 52a provided in the third portion P3 and the second emitter contact region 52b provided in the fourth portion P4.

The emitter contact 52C is connected to a third semiconductor region 13. Although FIG. 4 shows a cross section in which the emitter contact 52C is located on the third semiconductor region 13, the third semiconductor region 13 and the emitter contact 52C might not be in contact with each other depending on the position of the cross section. For example, as shown in FIG. 5, there may be a case where the emitter contact 52C extending into the semiconductor member 10M extends through the third semiconductor region 13 along the third direction D3, and the emitter contact 52C and a second semiconductor region 12 are in contact with each other in this cross section.

The gate metal layer 53L faces the semiconductor member 10M with the insulating layer 85a interposed therebetween.

Since the semiconductor device 100 according to the embodiment includes the first emitter contact region 52a and carriers can accordingly move via the first emitter contact region 52a, a decrease in RBSOA can be prevented.

A description will be given with reference to FIG. 5.

The first gate electrode 53a faces the second semiconductor region 12 of the semiconductor member 10M with the first insulating film 85b interposed therebetween. The first gate electrode 53a extends from the upper face of the semiconductor member 10M to the first semiconductor region 11.

A plurality of first gate electrodes 53a are provided side-by-side in the Y-direction. The first gate electrode 53a is, for example, connected to the gate metal layer 53L via the connection member 60 shown in FIG. 3, in a cross section not shown in FIG. 5.

Note that the embodiment is not limited to the examples shown in FIG. 2 and FIG. 5, and in addition to the first gate electrode 53a connected to the gate metal layer 53L, a dummy gate electrode embedded in a trench may be provided. The dummy gate electrode is electrically connected to the emitter electrode 52. The first gate electrodes 53a and the dummy gate electrodes are, for example, disposed cyclically in the Y-direction. For example, the first gate electrodes 53a and the dummy gate electrodes are disposed alternately in the Y-direction.

The operation of the semiconductor device 100 will be described with reference to FIG. 5. An IGBT is a type of power semiconductor device and enables high-speed switching of large power. An IGBT includes three electrodes, namely, a gate, a collector, and an emitter. The current flowing between the collector and the emitter is controlled by the voltage applied to the gate. When the voltage applied between the gate and the emitter and the voltage applied between the collector and the emitter are controlled, a channel in which electrons gather is formed in a layer facing the gate electrode, and the IGBT is turned on.

As shown in FIG. 3, the semiconductor device 100 according to the embodiment further includes the connection member 60 including a first connection portion 61. The first connection portion 61 is between the first gate electrode 53a and the first portion P1. The first connection portion 61 electrically connects the first portion P1 to the first gate electrode 53a. The connection member 60 including the first connection portion 61 is, for example, a metal plug. The first connection portion 61 is, for example, a metal containing W or Al.

Referring again to FIG. 2, a description will be given.

A first connection portion position 61P of the first connection portion 61 in the second direction D2 intersecting with the first direction D1 is different from a first contact region position 52aP of the first emitter contact region 52a in the second direction D2.

The gate electrode 53 of the semiconductor device 100 according to the embodiment further includes the second gate electrode 53b along the first direction D1. A direction from the second gate electrode 53b to the first gate electrode 53a is along the second direction D2. The second gate electrode 53b is disposed side-by-side, in the second direction D2, with the first gate electrode 53a located at the end in the negative direction of the second direction D2. The connection member 60 further includes a second connection portion 62. The second connection portion 62 is between the second gate electrode 53b and the second portion P2. The second connection portion 62 electrically connects the second portion P2 to the second gate electrode 53b at a second connection portion position 62P.

The length of the first gate electrode 53a along the first direction D1 is longer than the length of the second gate electrode 53b along the first direction D1. In the third direction D3 (Z-direction), at least a part of the second gate electrode 53b and the second portion P2 overlap.

The first contact region position 52aP is between the second connection portion position 62P of the second connection portion 62 and the first connection portion position 61P in the second direction D2.

A direction from the first emitter contact region 52a to the second emitter contact region 52b is along the first direction D1. The second emitter contact region 52b extends in, for example, the first direction D1.

The third portion P3 is between the first portion P1 and the second portion P2 in the first direction D1.

The gate metal layer 53L further includes a fifth portion P5. The fifth portion P5 is continuous with the first portion P1 and the second portion P2. A direction from the fifth portion P5 to the third portion P3 intersects with the first direction D1. A direction from the fifth portion P5 to the third portion P3 is along the second direction D2. The first portion P1 extends along the second direction D2, and the fifth portion P5 extends along the first direction D1. When the first portion P1 is said to extend along the second direction D2, this includes a case where the first portion P1 is defined in a portion, of the gate metal layer 53L, extending along the second direction D2.

The semiconductor device 100 according to the embodiment further includes the third gate electrode 53c along the first direction D1. A direction from the third gate electrode 53c to the second gate electrode 53b is along the second direction D2. In other words, the second gate electrode 53b and the third gate electrode 53c are disposed side-by-side in the second direction D2. The second gate electrode 53b is located between the first gate electrode 53a and the third gate electrode 53c in the second direction D2. The third gate electrode 53c extends along the first direction D1, and the length of the third gate electrode 53c in the first direction D1 is shorter than the length of the first gate electrode 53a in the first direction D1.

The gate metal layer 53L further includes a sixth portion P6. The sixth portion P6 is continuous with the fifth portion P5. A direction from the sixth portion P6 to the fifth portion P5 intersects with the first direction D1 (for example, is along the second direction D2). The sixth portion P6 extends, for example, along the second direction D2.

In the example shown in FIG. 2, the length of the fifth portion P5 in the first direction D1 is longer than the length thereof in the second direction D2. The length of the sixth portion P6 in the second direction D2 is longer than the length thereof in the first direction D1. The first portion P1 and the fifth portion P5 form, for example, an L-shaped portion of the gate metal layer 53L. The fifth portion P5, the second portion P2, and the sixth portion P6 form, for example, a T-shaped portion of the gate metal layer 53L. The second portion P2, a part of the fifth portion P5, and the sixth portion P6 extend along, for example, the second direction D2, and are connected to the second gate electrode 53b and the third gate electrode 53c.

The length of the second gate electrode 53b and that of the third gate electrode 53c in the first direction D1 are, for example, equal to each other, but are not limited to this.

The connection member 60 further includes a third connection portion 63. The third connection portion 63 is between the third gate electrode 53c and the sixth portion P6. Further, the third connection portion 63 is, for example, between the third gate electrode 53c and the fifth portion P5. The third connection portion 63 electrically connects the fifth portion P5 to the third gate electrode 53c. The third connection portion 63 electrically connects the fifth portion P5 and the sixth portion P6 to the third gate electrode 53c.

The emitter electrode 52 further includes a seventh portion P7. The seventh portion P7 is continuous with the third portion P3 and the fourth portion P4. The length of the seventh portion P7 in the first direction D1 is greater than the sum of the length of the third portion P3 in the first direction D1 and the length of the fourth portion P4 in the first direction D1. The length of the seventh portion P7 in the first direction D1 is equal to or greater than the sum of the length of the third portion P3 in the first direction D1, the length of the fourth portion P4 in the first direction D1, and the length of the second portion P2 in the first direction D1. The emitter electrode 52 is electrically connected to the semiconductor member 10M in the seventh portion P7. The second portion P2 is between the sixth portion P6 and the seventh portion P7 in the second direction D2.

The fifth portion P5, the second portion P2, and the seventh portion P7 are arranged in this order in the second direction D2. Further, the sixth portion P6, the fifth portion P5, the second portion P2, and the seventh portion P7 are arranged in this order in the second direction D2.

Referring again to FIG. 5, the semiconductor member 10M includes the first semiconductor region 11, the second semiconductor region 12, the third semiconductor region 13, and a fourth semiconductor region 14. The first semiconductor region 11 and the third semiconductor region 13 are, for example, of a first conductivity type. The second semiconductor region 12 and the fourth semiconductor region 14 are, for example, of a second conductivity type. The first conductivity type is one of the n-type and the p-type. The second conductivity type is the other of the n-type and the p-type. In the embodiment, the first conductivity type may be the p-type and the second conductivity type may be the n-type.

The second semiconductor region 12 is between the first semiconductor region 11 and the emitter electrode 52. The third semiconductor region 13 is between the second semiconductor region 12 and the emitter electrode 52. The third semiconductor region 13 is electrically connected to the emitter electrode 52. The fourth semiconductor region 14 is between the first semiconductor region 11 and the collector electrode 51. The emitter contact 52C extends, for example, into the semiconductor member 10M, and the second semiconductor region 12 is electrically connected to the emitter electrode 52.

In the semiconductor device 100, a third impurity concentration of the first conductivity type in the third semiconductor region 13 is higher than a first impurity concentration of the first conductivity type in the first semiconductor region 11. The first semiconductor region 11 is, for example, an n⁻-layer or an n-layer. The third semiconductor region 13 is, for example, an n⁺-layer.

In the semiconductor device 100, the concentration of the impurity of the first conductivity type in the first semiconductor region 11 is, for example, not less than 1×10¹³ cm⁻³ and not more than 1×10¹⁵ cm⁻³. The concentration of the impurity of the first conductivity type in the third semiconductor region 13 is, for example, not less than 1×10¹⁸ cm⁻³ and not more than 1×10²¹ cm⁻³. The concentration of the impurity of the second conductivity type in the second semiconductor region 12 is, for example, not less than 1×10¹⁵ cm⁻³ and not more than 1×10¹⁸ cm⁻³. The concentration of the impurity of the second conductivity type in the fourth semiconductor region 14 is, for example, not less than 1×10¹⁷ cm⁻³ and not more than 1×10¹⁹ cm⁻³.

In the semiconductor device 100, conductivity modulation occurs at the time of conduction, and the carrier density in the first semiconductor region 11 becomes higher than the impurity concentration of the first conductivity type and is, for example, not less than 1×10¹⁶ cm⁻³ and not more than 1×10¹⁸ cm⁻³.

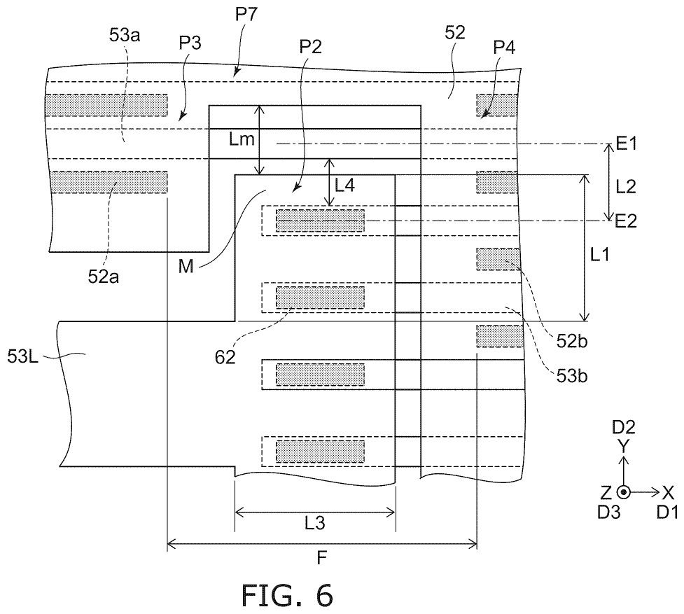

FIG. 6 is an enlarged view of the periphery of the second portion P2.

A first length L1 of the second portion P2 along the second direction D2 is not less than one time and not more than 15 times a second length L2, in the second direction D2, between a first center E1 of the first gate electrode 53a in the second direction D2 and a second center E2 of the second gate electrode 53b in the second direction D2. The first length L1 may be not less than one time and not more than 12 times the second length L2. The first length L1 may be not less than one time and not more than 10 times the second length L2. When the first length L1 is less than one time the second length L2, the length of the second portion P2 in the second direction D2 is not sufficient, and there may be a second gate electrode 53b that is unable to be connected to the second portion P2 of the gate metal layer 53L, or the first emitter contact region 52a may be unable to be provided in the third portion P3.

The length between the second portion P2 and the seventh portion P7 in the second direction D2 is defined as a margin length Lm. The margin length Lm is selected as appropriate such that the second portion P2 and the seventh portion P7 are spaced apart from each other. Since the first length L1 is not less than the second length L2, the first emitter contact region 52a and the second connection portion 62 (gate contact) can be provided within the range of length L1 +Lm in the second direction D2 with more certainty. Therefore, it is desirable that the first length L1 be not less than the second length L2. When the first length L1 is not less than one time the second length L2, it becomes easy to attain both the formation of the first emitter contact region 52a and the formation of the second connection portion 62 (gate contact).

When the first length L1 exceeds 15 times the second length L2, the area of the seventh portion P7 decreases in FIG. 2, and a region in which the emitter contact 52C is unable to be provided becomes too wide, which is not preferable.

The second length L2 is the sum of the width of the first gate electrode 53a (or the second gate electrode 53b) in the second direction D2 and the width L4 of a mesa M between the first gate electrode 53a and the second gate electrode 53b in the second direction D2. The second portion P2 and the mesa M overlap in the third direction D3. The first emitter contact region 52a is provided between the semiconductor member 10M and the third portion P3 at a position to which the mesa M extending in the first direction D1 is extended in the negative direction of the first direction D1. When the first length L1 is shorter than the second length L2, it may be difficult to form one second gate electrode 53b and one mesa M in a region below the second portion P2 and having a width of the first length L1 in the second direction D2. On the other hand, when the first length L1 is longer than or equal to the second length L2, it is possible to form at least one second gate electrode 53b and at least one mesa M in a region below the second portion P2 and having a width of the first length L1 in the second direction D2. It becomes easy to attain both the formation of the first emitter contact region 52a and the formation of the second connection portion 62 (gate contact).

The distance F (interval) between the first emitter contact region 52a and the second emitter contact region 52b in the first direction D1 may be not more than 40 μm. In the semiconductor device 100 according to the embodiment, the emitter contact 52C is not provided in the vicinity of the second portion P2, but its range is small, and therefore, current crowding to a nearby emitter contact is small. Therefore, breakdown caused by current crowding and latch-up is reduced.

The first length L1 may be not less than 1 μm and not more than 30 μm.

A third length L3 of the second portion P2 along the first direction D1 may be not less than 5 μm and not more than 30 μm. The distance F between the first emitter contact region 52a and the second emitter contact region 52 b may be not less than 20 μm and not more than 60 μm.

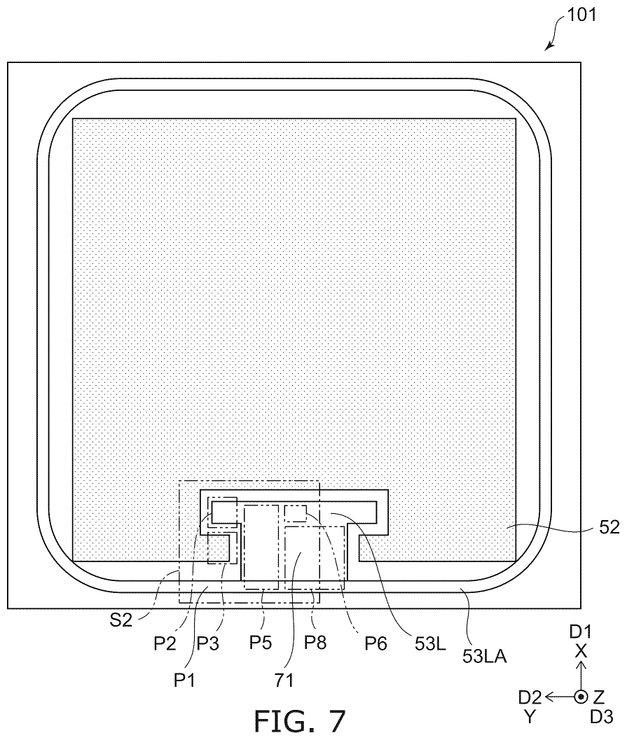

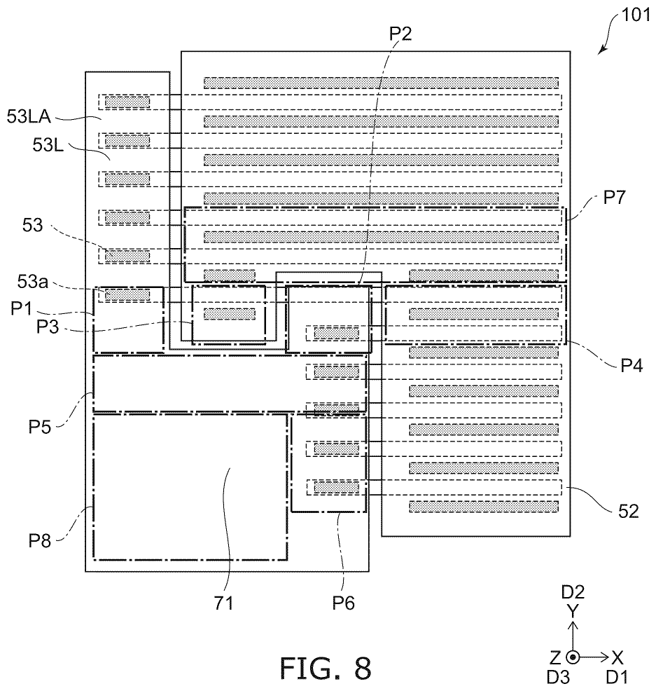

FIG. 7 and FIG. 8 are schematic plan views illustrating a semiconductor device according to a first modification of the embodiment. FIG. 8 shows a region S2 shown in FIG. 7.

As shown in FIG. 7, a semiconductor device 101 includes the gate metal layer 53L and the emitter electrode 52. The gate metal layer 53L includes the outer periphery 53LA surrounding the emitter electrode 52. Although not shown in FIG. 7, the gate electrode 53 extends along the first direction D1, and a portion, of the outer periphery 53LA, extending along the second direction D2 is connected to the gate electrode 53.

The gate metal layer 53L includes the first portion P1, the second portion P2, the fifth portion P5, the sixth portion P6, and an eighth portion P8, as will be described later with reference to FIG. 8. The gate metal layer 53L includes the first pad 71. The first pad 71 includes at least a part of the fifth portion P5, at least a part of the sixth portion P6, and the eighth portion P8, and is, for example, a gate pad.

As shown in FIG. 8, the gate metal layer 53L further includes the eighth portion P8. The eighth portion P8 is continuous with the fifth portion P5 and the sixth portion P6. A direction from the eighth portion P8 to the fifth portion P5 intersects with the first direction D1. The eighth portion P8 is provided in the negative direction of the Y-direction with respect to the fifth portion P5, and in the negative direction of the X-direction with respect to the sixth portion P6. A portion that is a combination of the fifth portion P5, the sixth portion P6, and the eighth portion P8 is the first pad 71.

The gate metal layer 53L includes the first portion P1, the second portion P2, and the first pad 71. The first pad 71 is provided continuously with the first portion P1. The first pad 71 is provided continuously with the second portion P2. The first portion P1 and the second portion P2 are continuous, with the first pad 71 interposed therebetween. The first portion P1 is a part of the outer periphery 53LA surrounding the emitter electrode 52. The first portion P1 and the second portion P2 are located in the positive direction of the second direction D2 with respect to the first pad 71. The first portion P1 extends from the first pad 71 in the positive direction of the second direction D2. The third portion P3 of the emitter electrode 52 is located in the positive direction of the second direction D2 with respect to the first pad 71. The third portion P3 is located on the same side as the direction in which the first portion P1 and the second portion P2 are located with respect to the first pad 71. In the first direction D1, the third portion P3 is located between the first portion P1 and the second portion P2.

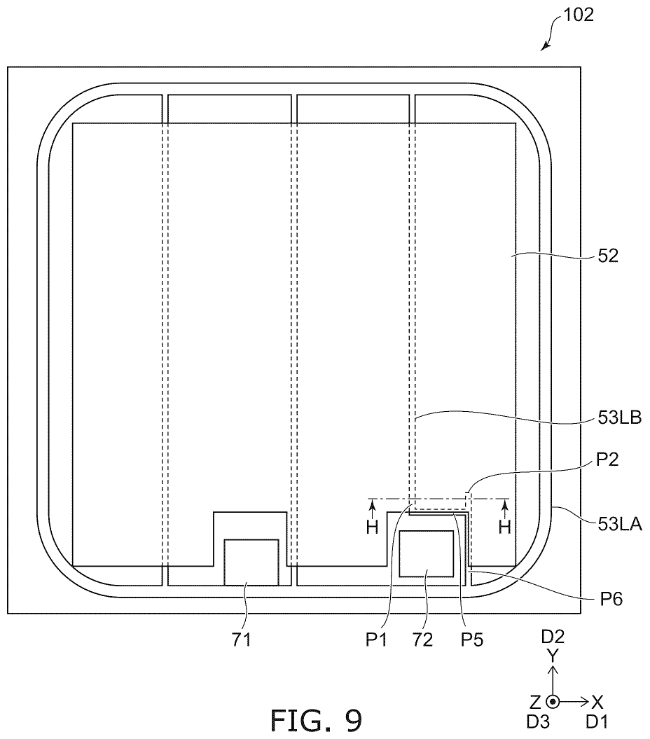

FIG. 9 is a schematic plan view illustrating a semiconductor device according to a second modification of the embodiment.

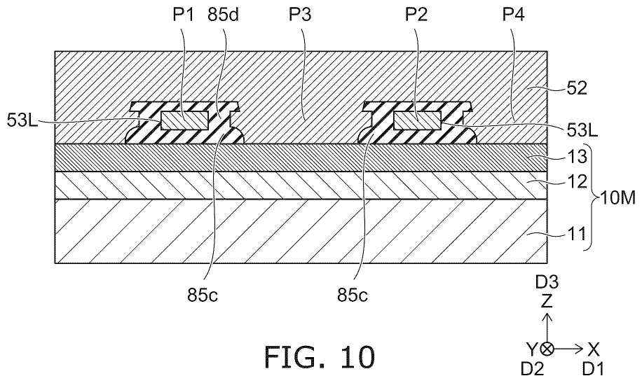

FIG. 10 is a cross-sectional view taken along line H-H of FIG. 9.

As shown in FIG. 9 and FIG. 10, a semiconductor device 102 includes the gate metal layer 53L and the emitter electrode 52. The gate metal layer 53L includes the first pad 71. The emitter electrode 52 overlaps at least a part of the gate metal layer 53L in the third direction D3.

The first pad 71 is provided on the semiconductor member 10M. The first pad 71 is electrically connected to the first portion P1 and the second portion P2. The first pad 71 is connected to the wiring 53 LB including the first portion P1 and the second portion P2, via the outer periphery 53LA. The first pad 71 is, for example, a gate pad.

The gate metal layer 53L includes the first portion P1 and the second portion P2. The first portion P1 extends along the second direction D2.

The semiconductor device 102 may include the second pad 72. The second pad 72 is provided on the semiconductor member 10M. The second pad 72 is insulated from the gate metal layer 53L. The second pad 72 is, for example, a pad, such as a temperature sensing pad, a gate pad of a multi-gate, or a current sensing pad.

The gate metal layer 53L includes the fifth portion P5 connected to the first portion P1 and extending in the first direction D1. The gate metal layer 53L includes the sixth portion P6 connected to the fifth portion P5 and the outer periphery 53LA and extending in the second direction D2. The second portion P2 is connected to the fifth portion P5 and is provided at a position opposite to the sixth portion P6 with respect to the fifth portion P5. The second pad 72 is adjacent to the fifth portion P5 and the sixth portion P6 and is insulated from the fifth portion P5 and the sixth portion P6.

FIG. 10 shows a cross section taken along line H-H of FIG. 9. The insulator 85 includes a second insulating film 85c and a third insulating film 85d. The second insulating film 85c is provided on the semiconductor member 10M. The gate metal layer 53L is provided on the second insulating film 85c. The third insulating film 85d is provided on the gate metal layer 53L so as to cover the gate metal layer 53L. The emitter electrode 52 is provided on the semiconductor member 10M and the second insulating film 85c.

The gate metal layer 53L is insulated from the semiconductor member 10M and the emitter electrode 52 by the second insulating film 85c and the third insulating film 85d. The semiconductor member 10M, the second insulating film 85c, the gate metal layer 53L, the third insulating film 85d, and a part of the emitter electrode 52 are provided in this order along the third direction D3.

In FIG. 10, a portion, of the emitter electrode 52, located between the second insulating film 85c and the third insulating film 85d surrounding the first portion P1, and the second insulating film 85c and the third insulating film 85d surrounding the second portion P2 in the first direction D1 is called the third portion P3. The third portion P3 is located between the first portion P1 and the second portion P2 in the first direction D1.

Note that the configuration shown as the second modification can also be applied to the layout shown in FIG. 7. That is, in FIG. 7, the wiring 53 LB of the gate metal layer 53L can be provided below the emitter electrode 52 similarly as in FIG. 9.

The semiconductor devices 100, 101, and 102 can be applied to semiconductor devices including a pad, such as a temperature sensing pad, a gate pad of a multi-gate, or a current sensing pad.

According to the embodiment, the semiconductor device 100 capable of preventing a decrease in RBSOA can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as the semiconductor member 10M, electrodes, conductive portions, insulating portions, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor member;
a gate metal layer including a first portion and a second portion;
a first gate electrode extending along a first direction, the first direction being from the first portion toward the second portion, the first gate electrode being connected to the gate metal layer in the first portion; and
an emitter electrode provided on the semiconductor member and including a third portion and a fourth portion, the emitter electrode being electrically connected to the semiconductor member in the third portion and the fourth portion, the second portion being between the third portion and the fourth portion in the first direction.

2. The semiconductor device according to claim 1, wherein the third portion is between the first portion and the second portion in the first direction.

3. The semiconductor device according to claim 1, wherein
the gate metal layer further includes a first pad provided on the semiconductor member, and
the first pad is connected to the first portion and the second portion.

4. The semiconductor device according to claim 3, wherein
the gate metal layer includes an outer periphery surrounding the emitter electrode, and
a wiring connecting opposing sides of the outer periphery, and
the first portion and the second portion are included in the wiring.

5. The semiconductor device according to claim 3, wherein the first portion and the second portion are continuous, with the first pad interposed therebetween, and the third portion is located on a same side as a direction in which the first portion and the second portion are located with respect to the first pad.

6. The semiconductor device according to claim 3, wherein the gate metal layer faces the semiconductor member and the emitter electrode with an insulating film interposed therebetween, and the semiconductor member, the insulating film, the gate metal layer, the insulating film, and the emitter electrode are stacked in this order.

7. The semiconductor device according to claim 1, wherein
the emitter electrode includes an emitter contact being in contact with the semiconductor member,
at least a part of the emitter contact extends along the first direction, and
the emitter contact includes a first emitter contact region provided in the third portion and a second emitter contact region provided in the fourth portion.

8. The semiconductor device according to claim 1, further comprising:
a second gate electrode along the first direction,
regarding a first length of the second portion along a second direction intersecting with the first direction, and a second length, in the second direction, between a first center of the first gate electrode in the second direction and a second center of the second gate electrode in the second direction, the first length being not less than the second length.

9. The semiconductor device according to claim 1, further comprising:
a second gate electrode along the first direction,
a direction from the second gate electrode to the first gate electrode being along a second direction intersecting with the first direction,
a length of the first gate electrode along the first direction being longer than a length of the second gate electrode along the first direction.

10. The semiconductor device according to claim 1, wherein
the gate metal layer further includes a fifth portion,
the fifth portion is continuous with the first portion and the second portion, and
a direction from the fifth portion to the third portion intersects with the first direction.

11. The semiconductor device according to claim 10, further comprising:
a connection member;
a second gate electrode along the first direction; and
a third gate electrode along the first direction,
the first gate electrode, the second gate electrode, and the third gate electrode being arranged in this order along a second direction intersecting with the first direction,
the gate metal layer further including a sixth portion,
the sixth portion being continuous with the fifth portion,
a direction from the sixth portion to the fifth portion intersecting with the first direction,
the connection member electrically connecting the sixth portion and the third gate electrode.

12. The semiconductor device according to claim 10, wherein
the first portion and the fifth portion form an L-shaped portion of the gate metal layer.

13. The semiconductor device according to claim 10, wherein
the gate metal layer further including a sixth portion,
the fifth portion, the second portion, and the sixth portion form a T-shaped portion of the gate metal layer.

14. The semiconductor device according to claim 3, further comprising:
a second pad provided on the semiconductor member,
the second pad being insulated from the gate metal layer.

15. The semiconductor device according to claim 14, wherein
the gate metal layer further includes a fifth portion,
the fifth portion is continuous with the first portion and the second portion, and
the fifth portion is located between the second pad and the third portion in a second direction intersecting with the first direction.

16. The semiconductor device according to claim 14, wherein the second pad is a temperature sensing pad.

17. The semiconductor device according to claim 14, wherein the second pad is a current sensing pad.
